(19) United States
(12) Patent Application Publication
(10) Pub. No.: US 2019/0096967 A1
(43) Pub. Date: Mar. 28, 2019

(54) ORGANIC ELECTROLUMINESCENT DISPLAY APPARATUS

(71) Applicant: Shenzhen China Star Optoelectronics Semiconductor Display Technology Co., Ltd., Shenzhen, Guangdong (CN)

(72) Inventors: Wenjie LI, Shenzhen, Guangdong (CN); Jinchuan LI, Shenzhen, Guangdong (CN); Tsungyuan WU, Shenzhen, Guangdong (CN); Feng WEI, Shenzhen, Guangdong (CN)

(21) Appl. No.: 15/574,697

(22) PCT Filed: Nov. 6, 2017
(86) PCT No.: PCT/CN2017/109462

§ 371 Date: Nov. 16, 2017

(30) Foreign Application Priority Data
Sep. 25, 2017 (CN) 201710872686.7

(51) Int. Cl. H01L 27/32; H01L 51/52; H01L 51/00; H01L 51/56

(52) U.S. Cl. CPC H01L 27/3246; H01L 51/5203; H01L 51/56; H01L 27/322; H01L 51/0005; H01L 51/5284

(57) ABSTRACT

In an organic electroluminescent display apparatus of the present disclosure, a pixel definition layer has an opening region and a non-opening region and a first electrode layer is arranged on the opening region of the pixel definition layer. A light-emitting function layer is arranged on the first electrode layer and a second electrode layer is arranged on the pixel definition layer and the light-emitting function layer. A first passivation layer is arranged on the second electrode layer. A black matrix is arranged on the first passivation layer and is arranged opposite to the non-opening region of the pixel definition layer. A color resistance unit is arranged on the first passivation layer and is adjacent to the black matrix.

### BACKGROUND OF THE INVENTION

### 1. Field of Invention

The present disclosure relates to the field of displays, and more particularly to an organic electroluminescent display apparatus.

### 2. Description of Prior Art

With development of display technology, flexible displays have become a main trend. Organic light emitting diodes (OLED) display technology is a main technology of the flexible display technology.

The OLED display technology combines a white organic light emitting device and a color filter to achieve full-color. As shown in FIG. 1, the color filter 1 is arranged on a cover plate 2, and comprises a black matrix 11, a red green blue (RGB) color resistance layer 12, an overcoat layer 13, and photo spacers 14. The photo spacers 14 are arranged between the overcoat layer 13 and a passivation layer 31 of the OLED device 3, which causes an excessive distance between devices and risks color mixing.

### SUMMARY OF THE INVENTION

The aim of the present disclosure is to provide an organic electroluminescent display apparatus to reduce distance between devices.

An embodiment of the present disclosure provides an organic electroluminescent display apparatus, where the organic electroluminescent display apparatus comprises a substrate, an organic electroluminescent device, and a color filter substrate.

The organic electroluminescent device comprises a pixel definition layer, a first electrode layer, a light-emitting function layer, a second electrode layer, and a first passivation layer.

The pixel definition layer has an opening region and a non-opening region, and the pixel definition layer is arranged on the substrate.

The first electrode layer is arranged on the opening region of the pixel definition layer.

The light-emitting function layer is arranged on the first electrode layer.

The second electrode layer is arranged on the pixel definition layer and the light-emitting function layer.

The first passivation layer is arranged on the second electrode layer.

The color filter substrate comprises a color resistance unit, a black matrix, and a second passivation layer.

The black matrix is arranged on the first passivation layer and is arranged opposite to the non-opening region of the pixel definition layer.

The color resistance unit is arranged on the first passivation layer and is adjacent to the black matrix.

The second passivation layer is arranged on the color resistance unit and the black matrix. The second passivation layer is composed of a single-layer film or multi-layer film.

In some embodiments, thickness of the second passivation layer ranges from 1000 nanometers to 2000 nanometers.

In some embodiments, the first passivation layer comprises a first inorganic sub-layer.

The first inorganic sub-layer is arranged on the second electrode layer. and composition material of the first inorganic sub-layer comprises silicon-containing oxides, silicon-containing nitrides, or aluminum-containing oxides.

In some embodiments, thickness of the first inorganic sub-layer ranges from 500 nanometers to 2000 nanometers.

In some embodiments, the first passivation layer further comprises an organic sub-layer and a second inorganic sub-layer.

The organic sub-layer is arranged on the first inorganic sub-layer and composition material of the organic sub-layer comprises transparent organic polymer resin or SiOC.

The second inorganic sub-layer is arranged on the organic sub-layer; and composition material of the second inorganic sub-layer comprises silicon-containing oxides, silicon-containing nitrides, or aluminum-containing oxides.

In some embodiments, thickness of the organic sub-layer ranges from 1 millimeter to 20 millimeters.

In some embodiments, thickness of the second inorganic sub-layer ranges from 500 nanometers to 1000 nanometers.

In some embodiments, temperature of thermal curing of the color resistance unit ranges from 90 degrees Celsius to 110 degrees Celsius.

In some embodiments, composition material of the black matrix comprises black resin, black inorganic oxide, sulfide, or fluorine-containing material.

The present disclosure provides an organic electroluminescent display apparatus. comprising a substrate, an organic electroluminescent device, and a color filter substrate.

The organic electroluminescent device comprises a pixel definition layer, a first electrode layer, a light-emitting function layer, a second electrode layer, and a first passivation layer.

The pixel definition layer has an opening region and a non-opening region, and the pixel definition layer is arranged on the substrate.

The first electrode layer is arranged on the opening region of the pixel definition layer.

The light-emitting function layer is arranged on the first electrode layer.

The second electrode layer is arranged on the pixel definition layer and the light-emitting function layer.

The first passivation layer is arranged on the second electrode layer.

The color filter substrate comprises a color resistance unit and a black matrix.

The black matrix is arranged on the first passivation layer and is arranged opposite to the non-opening region of the pixel definition layer.

The color resistance unit is arranged on the first passivation layer and is adjacent to the black matrix.

In some embodiments, the color filter substrate comprises a second passivation layer. The second passivation layer is arranged on the color resistance unit and the black matrix

In some embodiments, thickness of the second passivation layer ranges from 1000 nanometers to 2000 nanometers.

In some embodiments, the second passivation layer is composed of a single-layer film or multi-layer film.

In some embodiments, the first passivation layer comprises a first inorganic sub-layer.

The first inorganic sub-layer is arranged on the second electrode layer, and composition material of the first inorganic sub-layer comprises silicon-containing oxides, silicon-containing nitrides, or aluminum-containing oxides.

In some embodiments, thickness of the first inorganic sub-layer ranges from 500 nanometers to 2000 nanometers.

In some embodiments, the first passivation layer further comprises an organic sub-layer and a second inorganic sub-layer.

The organic sub-layer is arranged on the first inorganic sub-layer and composition material of the organic sub-layer comprises transparent organic polymer resin or SiOC.

The second inorganic sub-layer is arranged on the organic sub-layer; and composition material of the second inorganic sub-layer comprises silicon-containing oxides, silicon-containing nitrides, or aluminum-containing oxides.

In some embodiments, thickness of the organic sub-layer ranges from 1 millimeter to 20 millimeters.

In some embodiments, thickness of the second inorganic sub-layer ranges from 500 nanometers to 1000 nanometers.

In some embodiments, temperature of thermal curing of the color resistance unit ranges from 90 degrees Celsius to 110 degrees Celsius.

In some embodiments, composition material of the black matrix comprises black resin, black inorganic oxide, sulfide, or fluorine-containing material.

Compared with the organic electroluminescent display apparatus in prior art, the organic electroluminescent display apparatus of the present disclosure uses the color resistance unit arranged on the pixel, distance between devices is reduced.

In order to describe clearly the embodiment in the present disclosure, the description of preferred embodiments with reference to the accompanying drawings is as follows:

### BRIEF DESCRIPTION OF THE DRAWINGS

FIG. 1 is a structural diagram of an organic electroluminescent display apparatus in prior art.

FIG. 2 is a structural diagram of an organic electroluminescent display apparatus according to an embodiment of the present disclosure.

FIG. 3 is another structural diagram of the organic electroluminescent display apparatus according to the embodiment of the present disclosure.

FIG. 4 is another structural diagram of the organic electroluminescent display apparatus according to the embodiment of the present disclosure.

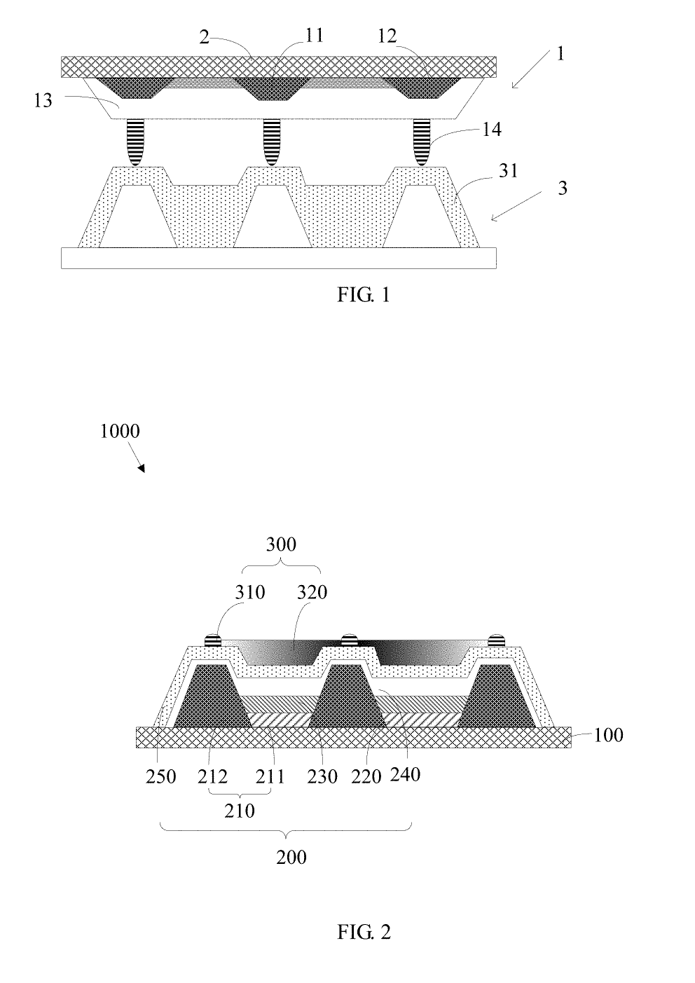

### DETAILED DESCRIPTION OF THE PREFERRED EMBODIMENTS

The following description of every embodiment with reference to the accompanying drawings is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure.

In the drawings, components having similar structures are denoted by the same numerals.

Reference throughout the specification to “embodiment” means that a particular feature, structure, or characteristic described in connection with the embodiment is included in at least one embodiment. Thus, appearances of the phrases “embodiment” in places throughout the specification may be combined in any suitable manner in one or more embodiments. Thus, the particular features, structures, or characteristics illustrated or described in connection with one embodiment may be combined, in whole or in part, with the features, structures, or characteristics of one or more other embodiments without limitation. Such modifications and variations are intended to be included within the scope of the present invention.

FIG. 2 is a structural diagram of an organic electroluminescent display apparatus according to an embodiment of the present disclosure. The organic electroluminescent display apparatus 1000 comprises a substrate 100, an organic electroluminescent device 200, and a color filter substrate 300. The substrate 100 is regarded as a thin-film transistor (TFT) substrate.

The organic electroluminescent device 200 is regarded as a white organic light emitting diode (OLED) device or a red-green-blue (RGB) OLED device. The organic electroluminescent device 200 may be prepared by adopting a hot evaporation method or adopting an inkjet printing method. To be specific, the organic electroluminescent device 200 comprises a pixel definition layer 210, a first electrode layer 220, a light-emitting function layer 230, a second electrode layer 240, and a first passivation layer 250.

The pixel definition layer 210 is arranged on the substrate 100, and the pixel definition layer 210 has an opening region 211 and a non-opening region 212.

The first electrode layer 220 comprises an anode, and the first electrode layer is arranged on the opening region of the pixel definition layer. The first electrode layer 220 may be made of transparent material, such as indium tin oxide (ITO).

The light-emitting function layer 230 is arranged on the first electrode layer 220. The light-emitting function layer 230 successively comprises a hole injection layer HIL, a hole transport layer HTL, and a light emitting layer EML, where the hole injection layer HIL is arranged on the first electrode layer 220. The hole injection layer HIL and the light emitting layer EML are prepared by adopting the inkjet printing method, and the hole transport layer HTL is prepared by adopting the hot evaporation method.

The second electrode layer 240 is arranged on the pixel definition layer 210 and the light-emitting function layer 230. The second electrode layer 240 comprises an electrical transport layer ETL and a cathode, where the cathode of the second electrode layer is prepared by adopting the inkjet printing method.

The first passivation layer 250 is arranged on the second electrode layer 240, and the first passivation layer 250 may be prepared from a single-layer film, and may be prepared from multi-layer film.

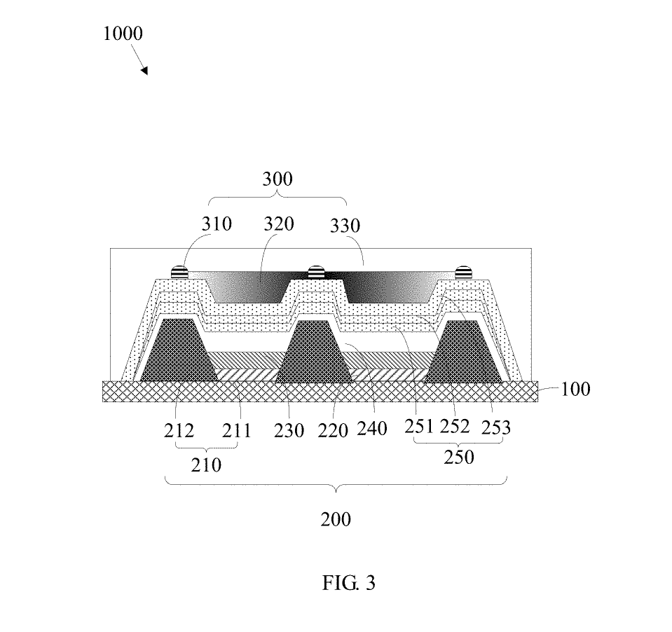

In some embodiments, as shown in FIG. 3, the first passivation layer 250 comprises a first inorganic sub-layer 251, where the first inorganic sub-layer 251 is prepared by adopting a chemical vapor deposition CVD, an atomic layer deposition ALD, or sputter coating method on the second electrode layer 240. The first inorganic sub-layer 251 is composed of a dense inorganic material. To be specific, composition materials of the first inorganic sub-layer comprises silicon-containing oxides, silicon-containing nitrides, or aluminum-containing oxides. In order to improve protection of the first passivation layer 250, thickness of the first inorganic sub-layer 251 ranges from 500 nanometers to 2000 nanometers. Furthermore, in order to increase speed of film formation in the CVD process, the thickness of the first inorganic sub-layer 251 is set as about 1000 nanometers.

In some embodiments, the first passivation layer 250 comprises a first inorganic sub-layer 251, an organic sub-layer 252, and a second inorganic sub-layer 253, to improve protection of the first passivation layer 250.

The organic sub-layer 252 is prepared by adopting the inkjet printing method or plasma enhanced chemical vapor deposition (PECVD) method on the first inorganic sub-layer 251. The organic sub-layer 252 has a buffer function, and composition material of the organic sub-layer comprises transparent organic polymer resin or SiOC. Thickness of the organic sub-layer ranges from 1 millimeter to 20 millimeters.

The second inorganic sub-layer 253 is arranged on the organic sub-layer 252. and composition material of the second inorganic sub-layer 253 comprises silicon-containing oxides, silicon-containing nitrides, or aluminum-containing oxides. Thickness of the second inorganic sub-layer 253 ranges from 500 nanometers to 1000 nanometers. It should be noted that when the organic electroluminescent display apparatus 1000 comprises three-layers film structure: the first inorganic sub-layer 251, the organic sub-layer 252, and the second inorganic sub-layer 253, the thickness of the first inorganic sub-layer 251 ranges from 500 nanometers to 1000 nanometers, where the thickness of the first inorganic sub-layer 251 is equal to or different from the thickness of the second inorganic sub-layer 253.

As shown in FIG. 2 or FIG. 3, the color filter substrate 300 comprises a color resistance unit 310 and a black matrix 320. The black matrix 320 is arranged on the first passivation layer 250 and is arranged opposite to the non-opening region 212 of the pixel definition layer 210. As shown in FIG. 2 or FIG. 3, the black matrix 320 and the first passivation layer 250 form grooves. The black matrix 320 is prepared by adopting the inkjet printing, silk-screen printing, sputter coating, hot evaporation, CVD, or physical vapor deposition (PVD) method.

The first half shell 101 is disposed on a front portion of the display device, where the first half shell 101 comprises a bottom surface and three side surfaces. Bottom ends of the three side surfaces are integrally formed with the bottom surface. Composition material of the black matrix 320 comprises black resin, black inorganic oxide, sulfide, or fluorine-containing material. When the black matrix 320 is prepared from the black resin, a curing operation is executed when the black resin is coated. In order to improve hydrophobicity of a surface of the back matrix 320, a surface treatment modification method is used or the black matrix 320 is prepared from a fluorine-containing material.

The color resistance unit 310 is arranged on the first passivation layer 250 and is adjacent to the black matrix 320. Namely the color resistance unit 310 forms in the grooves. As the color resistance unit 310 is arranged on the pixel, the manufacturing process of the organic electroluminescent display apparatus is simplified, and cost, distance between devices, and risks of color mixing are reduced.

The color resistance unit 310 is prepared from resin by printing organic solution containing red/green/blue dye or dispersing red/green/blue dye in organic polymer monomer method. Or the color resistance unit 310 is prepared by silk-screen printing or the inkjet printing method. As solvent and curing process are required during preparation of the color resistance unit 310, temperature of the color resistance unit 310 needs to be limited. To be specific, solvent is volatilized using reduced pressure evaporation method, and temperature of thermal curing of the color resistance unit ranges from 90 degrees Celsius to 110 degrees Celsius.

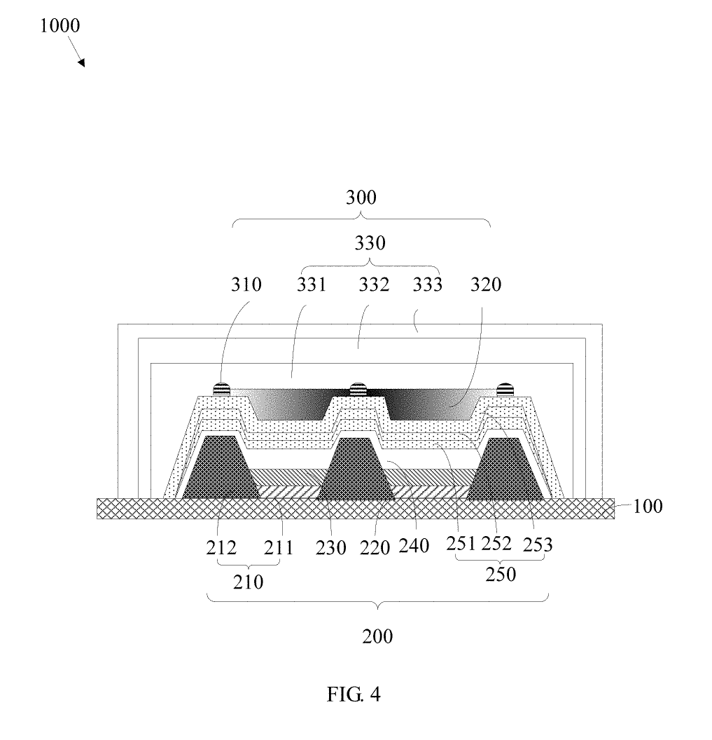

In some embodiments, as shown in FIG. 4, the color filter substrate 300 comprises a second passivation layer 330. The second passivation layer 330 is arranged on the color resistance unit 310 and the black matrix 320. The second passivation layer 330 may be prepared from a single-layer film, and may be prepared from multi-layer film. Thickness of the second passivation layer 330 ranges from 1000 nanometers to 2000 nanometers to avoid erosion by water and oxygen.

In some embodiments, as shown in FIG. 4, the second passivation layer 330 comprises a first inorganic sub-layer 331, where the first inorganic sub-layer 331 is prepared by adopting chemical vapor deposition CVD, atomic layer deposition ALD, or sputter coating method on the second electrode layer 240. The first inorganic sub-layer 331 is composed of a dense inorganic material. To be specific, composition materials of the first inorganic sub-layer comprises silicon-containing oxides, silicon-containing nitrides, or aluminum-containing oxides. Thickness of the first inorganic sub-layer 331 ranges from 500 nanometers to 2000 nanometers. Furthermore, in order to increase speed of film formation in the CVD process, the thickness of the first inorganic sub-layer 331 is set as about 1000 nanometers.

In some embodiments, the second passivation layer 330 comprises a first inorganic sub-layer 331, an organic sub-layer 332 and a second inorganic sub-layer 333.

The organic sub-layer 332 is prepared by adopting the inkjet printing method or plasma enhanced chemical vapor deposition (PECVD) method on the first inorganic sub-layer 331. Composition material of the organic sub-layer 332 comprises transparent organic polymer resin or SiOC. Thickness of the organic sub-layer ranges from 1 millimeter to 20 millimeters.

The second inorganic sub-layer 333 is arranged on the organic sub-layer 332, and composition material of the second inorganic sub-layer 333 comprises silicon-containing oxides, silicon-containing nitrides, or aluminum-containing oxides. Thickness of the second inorganic sub-layer 333 ranges from 500 nanometers to 1000 nanometers. It should be noted that when the organic electroluminescent display apparatus 1000 comprises three-layers film structure: the first inorganic sub-layer 331, the organic sub-layer 332 and the second inorganic sub-layer 333, the thickness of the first inorganic sub-layer 331 ranges from 500 nanometers to 1000 nanometers, where the thickness of the first inorganic sub-layer 331 is equal to or different from the thickness of the second inorganic sub-layer 333.

In some embodiments, the organic electroluminescent display apparatus 1000 further comprises an encapsulation layer. To be specific, a water-blocking thin film is adhered to the second passivation layer 330 to form the encapsulation layer. In some embodiments, the organic electroluminescent display apparatus 1000 further comprises a cover-plate. A cofferdam filled glue is coated on the cover-plate to form the encapsulation layer.

The organic electroluminescent display apparatus of the present disclosure uses that the color resistance unit 310 is arranged on the pixel, the manufacturing process of the organic electroluminescent display apparatus is simplified, and cost, distance between devices, and the risk of color mixing are reduced.

It should be understood that the present disclosure has been described with reference to certain preferred and alternative embodiments which are intended to be exemplary only and do not limit the full scope of the present disclosure as set forth in the appended claims.

What is claimed is:

1. An organic electroluminescent display apparatus, comprising: a substrate, an organic electroluminescent device, and a color filter substrate;
wherein the organic electroluminescent device comprises a pixel definition layer, a first electrode layer, a light-emitting function layer, a second electrode layer, and a first passivation layer;
wherein the pixel definition layer has an opening region and a non-opening region, and the pixel definition layer is arranged on the substrate;
wherein the first electrode layer is arranged on the opening region of the pixel definition layer;
wherein the light-emitting function layer is arranged on the first electrode layer;
wherein the second electrode layer is arranged on the pixel definition layer and the light-emitting function layer;
wherein the first passivation layer is arranged on the second electrode layer;
wherein the color filter substrate comprises a color resistance unit, a black matrix, and a second passivation layer;
wherein the black matrix is arranged on the first passivation layer and is arranged opposite to the non-opening region of the pixel definition layer;
wherein the color resistance unit is arranged on the first passivation layer and is adjacent to the black matrix;
wherein the second passivation layer is arranged on the color resistance unit and the black matrix; the second passivation layer is composed of a single-layer film or multi-layer film.

2. The organic electroluminescent display apparatus as claimed in claim 1, wherein thickness of the second passivation layer ranges from 1000 nanometers to 2000 nanometers.

3. The organic electroluminescent display apparatus as claimed in claim 1, wherein the first passivation layer comprises a first inorganic sub-layer;
wherein the first inorganic sub-layer is arranged on the second electrode layer, and composition material of the first inorganic sub-layer comprises silicon-containing oxides, silicon-containing nitrides, or aluminum-containing oxides.

4. The organic electroluminescent display apparatus as claimed in claim 3, wherein thickness of the first inorganic sub-layer ranges from 500 nanometers to 2000 nanometers.

5. The organic electroluminescent display apparatus as claimed in claim 3, wherein the first passivation layer further comprises an organic sub-layer and a second inorganic sub-layer;
wherein the organic sub-layer is arranged on the first inorganic sub-layer and composition material of the organic sub-layer comprises transparent organic polymer resin or SiOC;
wherein the second inorganic sub-layer is arranged on the organic sub-layer; and composition material of the second inorganic sub-layer comprises silicon-containing oxides, silicon-containing nitrides, or aluminum-containing oxides.

6. The organic electroluminescent display apparatus as claimed in claim 5, wherein thickness of the organic sub-layer ranges from 1 millimeter to 20 millimeters.

7. The organic electroluminescent display apparatus as claimed in claim 5, wherein thickness of the second inorganic sub-layer ranges from 500 nanometers to 1000 nanometers.

8. The organic electroluminescent display apparatus as claimed in claim 1, wherein temperature of thermal curing of the color resistance unit ranges from 90 degrees Celsius to 110 degrees Celsius.

9. The organic electroluminescent display apparatus as claimed in claim 1, composition material of the black matrix comprises black resin, black inorganic oxide, sulfide or fluorine-containing material.

10. An organic electroluminescent display apparatus, comprising: a substrate; an organic electroluminescent device, and a color filter substrate;
wherein the organic electroluminescent device comprises a pixel definition layer, a first electrode layer, a light-emitting function layer, a second electrode layer, and a first passivation layer;
wherein the pixel definition layer has an opening region and a non-opening region, and the pixel definition layer is arranged on the substrate;
wherein the first electrode layer is arranged on the opening region of the pixel definition layer;
wherein the light-emitting function layer is arranged on the first electrode layer;
wherein the second electrode layer is arranged on the pixel definition layer and the light-emitting function layer;
wherein the first passivation layer is arranged on the second electrode layer;
wherein the color filter substrate comprises a color resistance unit and a black matrix;
wherein the black matrix is arranged on the first passivation layer and is arranged opposite to the non-opening region of the pixel definition layer;
wherein the color resistance unit is arranged on the first passivation layer and is adjacent to the black matrix.

11. The organic electroluminescent display apparatus as claimed in claim 10, wherein the color filter substrate comprises a second passivation layer; wherein the second passivation layer is arranged on the color resistance unit and the black matrix.

12. The organic electroluminescent display apparatus as claimed in claim 11, wherein thickness of the second passivation layer ranges from 1000 nanometers to 2000 nanometers.

13. The organic electroluminescent display apparatus as claimed in claim 10, wherein the second passivation layer is composed of a single-layer film or multi-layer film.

14. The organic electroluminescent display apparatus as claimed in claim 10, wherein the first passivation layer comprises a first inorganic sub-layer;
wherein the first inorganic sub-layer is arranged on the second electrode layer, and composition materials of the first inorganic sub-layer comprises silicon-containing oxides, silicon-containing nitrides, or aluminum-containing oxides.

15. The organic electroluminescent display apparatus as claimed in claim 14, wherein thickness of the first inorganic sub-layer ranges from 500 nanometers to 2000 nanometers.

16. The organic electroluminescent display apparatus as claimed in claim 14, wherein the first passivation layer further comprises an organic sub-layer and a second inorganic sub-layer;
wherein the organic sub-layer is arranged on the first inorganic sub-layer and composition materials of the organic sub-layer comprises transparent organic polymer resin or Sioc;
wherein the second inorganic sub-layer is arranged on the organic sub-layer; and composition materials of the second inorganic sub-layer comprise silicon-containing oxides, silicon-containing nitrides, or aluminum-containing oxides.

17. The organic electroluminescent display apparatus as claimed in claim 16, wherein thickness of the organic sub-layer ranges from 1 millimeter to 20 millimeters.

18. The organic electroluminescent display apparatus as claimed in claim 16, wherein thickness of the second inorganic sub-layer ranges from 500 nanometers to 1000 nanometers.

19. The organic electroluminescent display apparatus as claimed in claim 10, wherein temperature of thermal curing of the color resistance unit ranges from 90 degrees Celsius to 110 degrees Celsius.

20. The organic electroluminescent display apparatus as claimed in claim 1, composition materials of the black matrix comprises black resin, black inorganic oxide, sulfide, or fluorine-containing material.
